(19) United States
(12) Patent Application Publication
(10) Pub. No.: US 2025/0191817 A1
(43) Pub. Date: Jun. 12, 2025

(54) MANUFACTURING OF SHIELDED MULTI-WIRE CABLE ASSEMBLIES

(71) Applicant: BIOSENSE WEBSTER (ISRAEL) LTD., Yokneam (IL)

(72) Inventors: Assaf Govari, Haifa (IL); Ilya Sitnitsky, Nahariya (IL); Alexander Shechtman, Haifa (IL); Sergey Sobol, Haifa (IL); Faina Oriya Luria, Yoqneam Moshava (IL); Andres Claudio Altmann, Haifa (IL)

(21) Appl. No.: 18/947,022

(22) Filed: Nov. 14, 2024

Related U.S. Application Data
(60) Provisional application No. 63/608,869, filed on Dec. 12, 2023.
(60) Provisional application No. 63/608,872, filed on Dec. 12, 2023.

(51) Int. Cl. H01B 13/26; H01B 7/22; H01B 13/02; H05K 9/00

(52) U.S. Cl. CPC H01B 13/26; H01B 13/0207; H01B 13/0271; H01B 7/226; H05K 9/0098

(57) ABSTRACT

A method includes providing a pre-assembled cable assembly including a plurality of wires and a circuit board. The pre-assembled cable assembly has a first end and a second end, and the wires are connected to the circuit board at the second end. The pre-assembled cable assembly is gripped at the first end and at the second end. While the pre-assembled cable assembly is gripped, an electromagnetic shield is applied around the wires.

### CROSS-REFERENCE TO RELATED APPLICATION

This application claims the benefit of U.S. Provisional Patent Applications 63/608,869 and 63/608,872, both filed Dec. 12, 2023, whose disclosures are incorporated herein by reference.

### FIELD OF THE DISCLOSURE

The present disclosure relates generally to electronic wiring, and particularly to methods and systems for manufacturing cable assemblies.

### BACKGROUND OF THE DISCLOSURE

Various electronic systems comprise cable assemblies including multiple wires. One typical example is a multi-electrode catheter, in which each electrode is coupled to a respective wire for transferring a signal sensed by the electrode. Some catheters may comprise tens of electrodes or more, meaning that a large number of wires need to pass through a small-diameter catheter shaft.

The present disclosure will be more fully understood from the following detailed description of the embodiments thereof, taken together with the drawings in which:

### BRIEF DESCRIPTION OF THE DRAWINGS

FIG. 1 is a diagram that schematically illustrates a system for manufacturing shielded cable assemblies, in accordance with an example described herein;

FIG. 2 is a diagram that schematically illustrates details of a fixture in the system of FIG. 1, in accordance with an example described herein;

FIG. 3 is a diagram that schematically illustrates a device for wrapping an electromagnetic shield around a set of wires of a cable assembly, in accordance with an example described herein; and

FIG. 4 is a flow chart that schematically illustrates a method for manufacturing shielded cable assemblies, in accordance with an example described herein.

### DETAILED DESCRIPTION OF EXAMPLES

### Overview

Examples that are described herein provide improved methods and systems for manufacturing electromagnetically shielded cable assemblies. The examples described below refer mainly to cable assemblies that connect a multi-electrode catheter to an external console. These examples, however, are by no means limiting. The disclosed techniques can be used to manufacture cable assemblies for use in any suitable system or application.

As a demonstrative example, consider a catheter comprising a shaft and a distal end, the distal end comprising multiple electrodes. Multiple wires run through the shaft. The wires are connected, e.g., soldered and/or welded to a circuit board fitted at the distal end for connecting to the electrodes. The wires may also be connected, e.g., soldered and/or welded to another circuit board at the proximal end of the shaft, e.g., at a handle of the catheter or at a connector that plugs into the console.

In some examples, the multiple wires are cut to their final length and connected to at least one circuit board before being fitted in the shaft. The circuit board and the wires connected thereto are referred to herein as a “pre-assembled cable assembly” (or simply “cable assembly” for brevity). In some examples, the pre-assembled cable assembly comprises two circuit boards, one at each end of the plurality of wires. Example methods and systems for producing such cable assemblies are described in U.S. Provisional Patent Application entitled “Cable Manufacturing Process,” Attorney Docket Number BIO6865USPSP1, cited above.

In many practical applications, it is desirable to twist the wires of the cable assembly, and shield the wires of the cable assembly from Electromagnetic Interference (EMI). For this purpose, an electromagnetic shield may be applied around the set of wires before the cable assembly is fitted in the shaft. In some examples, shielding is applied during twisting, e.g., by adding one or more wires that are connected to ground, and twisting the plurality of wires including the additional ground wire(s). Additionally, or alternatively, the wires are twisted before applying the electromagnetic shield. Systems and methods for applying an electromagnetic shield to pre-assembled cable assemblies are described herein.

In some examples, a manufacturing system comprises first and second fixtures for holding respective first and second ends of a pre-assembled cable assembly. For example, when the pre-assembled cable assembly comprises a circuit board at each end, the fixtures may comprise baseplates for mounting the two circuit boards. An electromagnetic shield is applied around the wires while the cable assembly is held by the fixtures.

The electromagnetic shield may comprise, for example, an electrically conductive foil, braid or wire that is wound around the plurality of wires. Alternatively, the electromagnetic shield may be applied by spraying the plurality of wires with an electrically conductive material, by dipping the plurality of wires in an electrically conductive material, or in any other suitable way. In some examples, an electrically-insulating jacket is applied to the cable after shielding.

In one example, at least one of the fixtures comprises a stretching device (e.g., a spring), which is configured to maintain the tension of the wires within a pre-specified range while the electromagnetic shield is applied. Additionally, or alternatively, at least one of the fixtures comprises a rotation device (e.g., a motor), which is configured to roll the corresponding end of the pre-assembled cable assembly, thereby twisting the wires around one another, before applying the electromagnetic shield.

In some examples, the system comprises one or more tension sensors that monitor the tension of the wires and control the stretching device, so as to retain the tension within the pre-specified range. The thinner and more delicate the wires, the more important it is to maintain proper tension to avoid tearing. On the other hand, insufficient tension may degrade the quality of twisting and/or shielding.

When using the disclosed techniques, the plurality of wires is twisted, and the electromagnetic shield is subsequently applied, after the wires have been cut to the proper length and connected to at least one circuit board. This technique is in contrast to the known method of drawing wires from a spool, and cutting them for use in individual cable assemblies. The disclosed techniques are advantageous, for example, because they enable complete automation of the entire cable assembly process.

### System Description

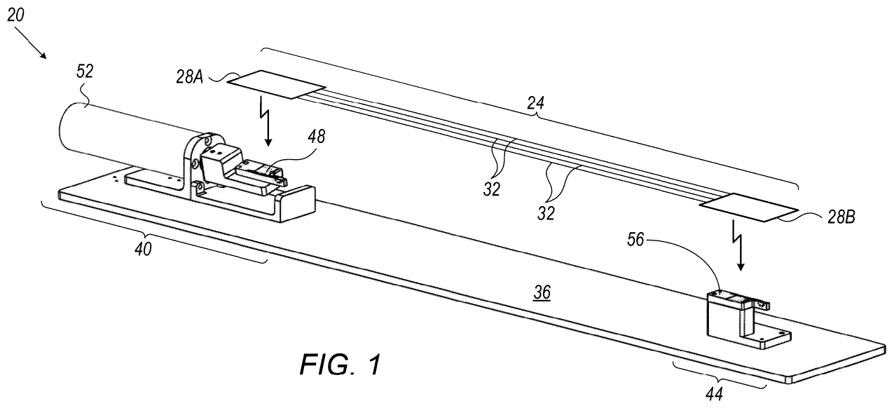

FIG. 1 is a diagram that schematically illustrates a system (“jig”) 20 for manufacturing shielded cable assemblies, in accordance with an example described herein. An example of a shielded cable assembly 24, manufactured using system 20, is shown at the top of the figure.

In the present example, cable assembly 24 comprises a circuit board 28A at one end, another circuit board 28B and the other end, and a set of electrical wires 32 connecting circuit boards 28A and 28B. Circuit boards 28A and 28B typically comprise Printed Circuit Boards (PCBs). Each wire 32 typically comprises an electrically conductive (e.g., copper) core surrounded by an insulating layer. One end of each wire 32 is typically connected to a respective pad on circuit board 28A, and at the other end to a respective pad on circuit board 28B.

In one example, the length of each wire 32 (and thus of assembly 24) is on the order of 1.5 m, the wires are gauge 48 wires, and the number of wires is 5-15, e.g., ten.

Alternatively, any other suitable sizes and number of wires can be used.

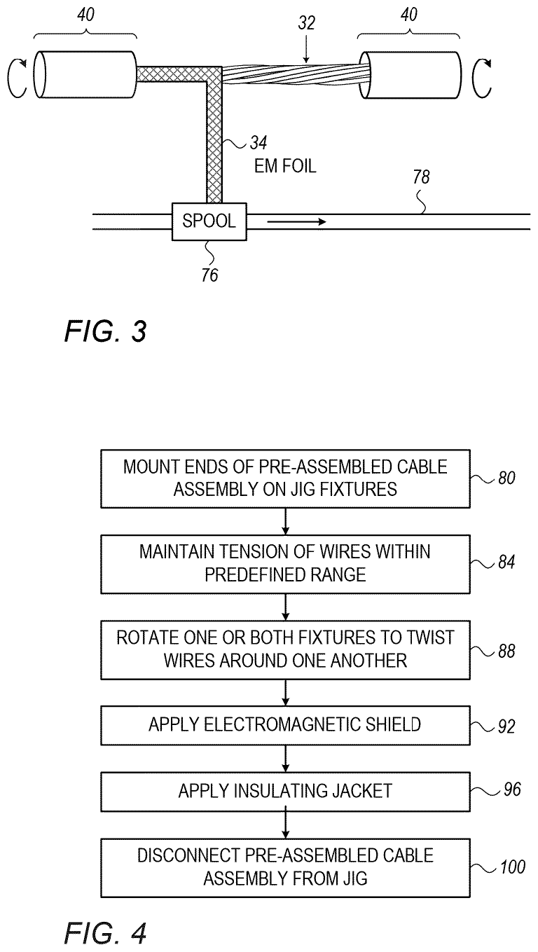

An electromagnetic shield (seen in FIG. 3 below) is applied around the set of wires 32. Typically, although not necessarily, the electromagnetic shield is applied after wires 32 are twisted. In some examples, the electromagnetic shield comprises a strip of metal (e.g., aluminum) foil that is wrapped around wires 32. In alternative examples, the shield may comprise a braid (mesh) of metal wires that is wrapped around wires 32. An example device for wrapping a strip of foil or mesh around wires 32 is shown in FIG. 3 below.

Further alternatively, the electromagnetic shield may comprise a single metal wire that is wound around wires 32. As yet another example, the electromagnetic shield may comprise a layer of electrically conductive applied onto the set of wires 32 by spraying or dipping. Other suitable electromagnetic shields can also be used. At each end, the electromagnetic shield is typically connected to a ground layer of the respective circuit board. After shielding, an electrically-insulating jacket may be applied to the cable.

The example of FIG. 1 refers to a cable assembly having two circuit boards. In alternative examples, cable assembly 24 may comprise only one circuit board. In these examples, each wire 32 is connected to the circuit board at one end and remains open ended at the other end.

Manufacturing system 20 of FIG. 1 comprises a main fixture 40 and an auxiliary fixture 44, both fixed to a base 36. Main fixture 40 comprises a baseplate 48 for mounting circuit board 28A. Auxiliary fixture 44 comprises a baseplate 56 for mounting circuit board 28B. The distance between fixtures 48 and 56 corresponds to the length of wires 32, so that wires 32 are held at a tension when circuit boards 28A and 28B are mounted on baseplates 48 and 56, respectively. A mechanism for maintaining the proper tension is described further below.

Main fixture 40 further comprises an electrical motor 52. Baseplate 48 is mounted on the axis of motor 52. When circuit boards 28A and 28B are mounted on baseplates 48 and 56, rotating motor 52 will rotate baseplate 48, thereby twisting the set of wires 32. Motor 52 is regarded as an example of a rotation device that rotates at least one end of the pre-assembled cable assembly while the electromagnetic shield is applied. In alternative examples, any other suitable type of rotation device can be used. For example, an alternative rotation device may rotate both ends of cable assembly 24 in opposite directions.

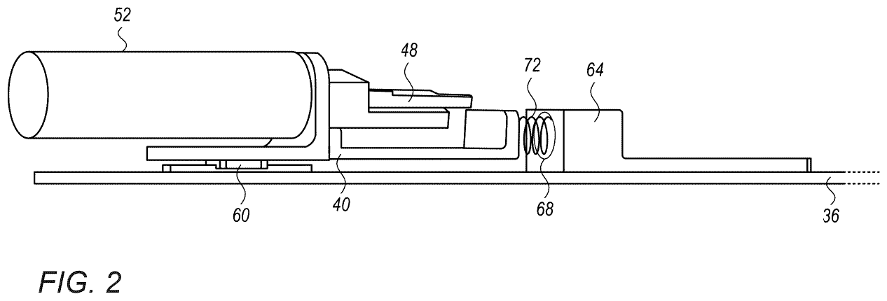

FIG. 2 is a diagram that schematically illustrates details of main fixture 40 of system 20, in accordance with an example described herein. As seen, fixture 40 is mounted on a slider 60 that enables the fixture (including motor 52 and baseplate 48) to move axially relative to base 36. In addition, a block 64 having a cylindrical cavity 68 is mounted on base 36 adjacent to fixture 40. A spring 72 is placed in cavity 72 and presses against fixture 40. The mechanical force that spring 72 exerts on fixture 40 is chosen to set the tension of wires 32 in a defined range. Slider 60 and spring 72 thus form a stretching device that maintains the tension of wires 32 within a predefined range while the electromagnetic shield is applied. In alternative examples, any other suitable type of stretching device can be used. For example, an alternative stretching device may stretch both ends of cable assembly 24, i.e., apply a stretching force both at fixture 40 and at fixture 44.

As noted above, in some examples the stretching device is controlled by one or more tension sensors that monitor the tension of the wires. The tension sensor or sensors (or a controller coupled thereto) adjusts the tension applied by the stretching device, so as to maintain the tension within a pre-specified range.

The configuration of system 20, as depicted in FIGS. 1 and 2, is an example configuration that was chosen purely for the sake of conceptual clarity. In alternative examples, any other suitable configuration can be used. For example, when the pre-assembled cable assembly comprises only one circuit board, one of the baseplates (48 or 56) may be replaced by a suitable gripper that grips the open-ended ends of wires 32.

In various implementations, system 20 may comprise various shielding devices for applying the electromagnetic shield. In one example, system 20 comprises a bobbin or spool (see FIG. 3 below) that dispenses a metal foil, braid or wire around the set of wires 32. Alternatively, system 20 may comprise a suitable sprayer for spraying an electrically conductive material onto the set of wires 32.

Further alternatively, system 20 may comprise a suitable reservoir for dipping the set of wires in an electrically conductive liquid. System 20 may also comprise a suitable drier for drying the material after dipping. Any other suitable techniques can be used for applying the electromagnetic shield.

FIG. 3 is a diagram that schematically illustrates a device for wrapping an electromagnetic shield around a set of wires of a cable assembly, in accordance with an example described herein. In the present example, both fixtures 40 and 44 are rotatable. The set of wires 32 is held between fixtures 40 and 44, after having been twisted. A spool 76 is configured to dispense an electromagnetic shield 34, in the present example a strip of metallic foil. Spool 76 is also movable along an axle 78.

To apply electromagnetic shield 34, fixtures 40 and 44 are rotated together. At the same time, spool 76 is moved slowly along axle 78. As a result, the strip of foil 34 is drawn from spool 76 and wrapped around wires 32.

The wrapping device of FIG. 3 is one non-limiting example of a shielding device. Any other suitable shielding device can be used in alternative examples.

FIG. 4 is a flow chart that schematically illustrates a method for manufacturing shielded cable assemblies, in accordance with an example described herein. The method begins with a user (e.g., production line staff) mounting a pre-assembled cable assembly on the fixtures of system 20, at a mounting operation 80. With reference to FIG. 1, the mounting operation comprises mounting circuit board 28A on baseplate 48, and mounting circuit board 28B on baseplate 56.

At a stretching operation 84, the stretching device of system 20 (in the present example spring 72 and slider 60 of FIG. 2) maintain the desired tension in wires 32. At a twisting operation 88, the rotation device of system 20 (in the present example motor 52) twists the set of wires 32 around one another.

At a shielding operation 92, the shielding device of system 20 (e.g., bobbin mechanism or any other) applies electromagnetic shield 34 around the twisted wires 32. At a jacketing operation 96, an electrically-insulating jacket shielded cable assembly. At is applied to the a disconnection operation 100, the user disconnects and removes the shielded cable assembly 24 from system 20. The flow of FIG. 4 is an example flow that is chosen purely for the sake of conceptual clarity. In alternative embodiments, any other suitable flow of operations can be used. For example, the method may include an additional step of applying an external, electrically insulating jacket surrounding the electromagnetic shield.

### EXAMPLES

### Example 1

A method includes providing a pre-assembled cable assembly including a plurality of wires and a circuit board. The pre-assembled cable assembly has a first end and a second end, and the wires are connected to the circuit board at the second end. The pre-assembled cable assembly is gripped at the first end and at the second end. While the pre-assembled cable assembly is gripped, an electromagnetic shield is applied around the wires.

### Example 2

The method according to example 1, wherein applying the electromagnetic shield comprises dispensing the electromagnetic shield from a spool while rotating the gripped pre-assembled cable assembly, thereby wrapping the electromagnetic shield around the wires.

### Example 3

The method according to example 2, further comprising moving the spool alongside the cable assembly while dispending the electromagnetic shield.

### Example 4

The method according to example 1, wherein the pre-assembled cable assembly further includes an additional circuit board connected to the wires at the second end.

### Example 5

The method according to example 1, further including twisting the plurality of wires around one another before applying the electromagnetic shield.

### Example 6

The method according to example 5, wherein twisting the plurality of wires includes rolling the first and second ends of the pre-assembled cable assembly with respect to one another.

### Example 7

The method according to example 1, wherein gripping the pre-assembled cable assembly includes maintaining a tension of the wires within a pre-specified range.

### Example 8

The method according to example 1, wherein applying the electromagnetic shield includes wrapping the wires with one or more of (i) an electrically conductive foil, (ii) an electrically conductive wire and (iii) an electrically conductive braid.

### Example 9

The method according to example 1, wherein applying the electromagnetic shield includes spraying the wires with an electrically conductive material.

### Example 10

The method according to example 1, wherein applying the electromagnetic shield includes dipping the wires in an electrically conductive material.

### Example 11

The method according to example 1, further including applying an external electrically insulating jacket surrounding the electromagnetic shield.

### Example 12

A system includes first and second fixtures configured to hold respective first and second ends of a pre-assembled cable assembly. The pre-assembled cable assembly includes a circuit board and a plurality of wires connected to the circuit board at the first end, for an applying electromagnetic shield around the wires. At least one of the first and second fixtures includes a stretching device, configured to maintain a tension of the wires within a pre-specified range while an electromagnetic shield is applied around the wires.

### Example 13

A system includes first and second fixtures configured to hold respective first and second ends of a pre-assembled cable assembly. The pre-assembled cable assembly includes a circuit board and a plurality of wires connected to the circuit board at the first end, for applying an electromagnetic shield around the wires. At least one of the first and second fixtures includes a rotation device, configured to roll at least one of the first and second ends of the pre-assembled cable assembly, thereby twisting the plurality of wires around one another, before applying the electromagnetic shield.

It will be appreciated that the embodiments described above are cited by way of example, and that the present invention is not limited to what has been particularly shown and described hereinabove. Rather, the scope of the present invention includes both combinations and sub-combinations of the various features described hereinabove, as well as variations and modifications thereof which would occur to persons skilled in the art upon reading the foregoing description and which are not disclosed in the prior art. Documents incorporated by reference in the present patent application are to be considered an integral part of the application except that to the extent any terms are defined in these incorporated documents in a manner that conflicts with the definitions made explicitly or implicitly in the present specification, only the definitions in the present specification should be considered.

1. A method, comprising:
providing a pre-assembled cable assembly comprising a plurality of wires and a circuit board, wherein the pre-assembled cable assembly has a first end and a second end, and wherein the wires are connected to the circuit board at the second end;
gripping the pre-assembled cable assembly at the first end and at the second end; and
while the pre-assembled cable assembly is gripped, applying an electromagnetic shield around the wires.

2. The method according to claim 1, wherein applying the electromagnetic shield comprises dispensing the electromagnetic shield from a spool while rotating the gripped pre-assembled cable assembly, thereby wrapping the electromagnetic shield around the wires.

3. The method according to claim 2, further comprising moving the spool alongside the cable assembly while dispending the electromagnetic shield.

4. The method according to claim 1, wherein the pre-assembled cable assembly further comprises an additional circuit board connected to the wires at the second end.

5. The method according to claim 1, further comprising twisting the plurality of wires around one another before applying the electromagnetic shield.

6. The method according to claim 5, wherein twisting the plurality of wires comprises rolling the first and second ends of the pre-assembled cable assembly with respect to one another.

7. The method according to claim 1, wherein gripping the pre-assembled cable assembly comprises maintaining a tension of the wires within a pre-specified range.

8. The method according to claim 1, wherein applying the electromagnetic shield comprises wrapping the wires with one or more of (i) an electrically conductive foil, (ii) an electrically conductive wire and (iii) an electrically conductive braid.

9. The method according to claim 1, wherein applying the electromagnetic shield comprises spraying the wires with an electrically conductive material.

10. The method according to claim 1, wherein applying the electromagnetic shield comprises dipping the wires in an electrically conductive material.

11. The method according to claim 1, further comprising applying an external electrically insulating jacket surrounding the electromagnetic shield.

12. A system, comprising:
first and second fixtures configured to hold respective first and second ends of a pre-assembled cable assembly, the pre-assembled cable assembly comprising a circuit board and a plurality of wires connected to the circuit board at the first end, for applying an electromagnetic shield around the wires;
wherein at least one of the first and second fixtures comprises a stretching device, configured to maintain a tension of the wires within a pre-specified range while an electromagnetic shield is applied around the wires.

13. The system according to claim 12, further comprising:
a spool, configured to dispense the electromagnetic shield; and
a rotation device configured to rotate the gripped pre-assembled cable assembly while the electromagnetic shield is being dispensed from the spool, thereby wrapping the electromagnetic shield around the wires.

14. The system according to claim 13, wherein the spool is configured to move alongside the cable assembly while dispending the electromagnetic shield.

15. The system according to claim 12, further comprising a rotation device configured to twist the plurality of wires around one another before applying the electromagnetic shield.

16. The system according to claim 12, wherein the electromagnetic shield comprises one or more of (i) an electrically conductive foil, (ii) an electrically conductive wire and (iii) an electrically conductive braid.

17. A system, comprising:
first and second fixtures configured to hold respective first and second ends of a pre-assembled cable assembly, the pre-assembled cable assembly comprising a circuit board and a plurality of wires connected to the circuit board at the first end, for applying an electromagnetic shield around the wires;
wherein at least one of the first and second fixtures comprises a rotation device, configured to roll at least one of the first and second ends of the pre-assembled cable assembly, thereby twisting the plurality of wires around one another, before applying the electromagnetic shield.

18. The system according to claim 17, further comprising a stretching device configured to maintain a tension of the wires within a pre-specified range.
